(19) United States
(12) Patent Application Publication
(10) Pub. No.: US 2017/0176853 A1
(43) Pub. Date: Jun. 22, 2017

(54) NANO-IMPRINTING TEMPLATE, SYSTEM, AND IMPRINTING METHOD

(71) Applicant: SOUTH UNIVERSITY OF SCIENCE AND TECHNOLOGY OF CHINA, Shenzhen, Guangdong (CN)

(72) Inventors: Xing Cheng, Shenzhen (CN); Dehu Cui, Shenzhen (CN); Ziping Li, Shenzhen (CN); Jing Ming, Shenzhen (CN); Zhong Zhang, Shenzhen (CN)

(21) Appl. No.: 15/117,046

(22) PCT Filed: Mar. 5, 2014
(86) PCT No.: PCT/CN2014/072903

§ 371 Date: Aug. 5, 2016

(30) Foreign Application Priority Data
Feb. 7, 2014 (CN) 201410044777.8

(51) Int. Cl. G03F 7/00; B29C 59/00; B29C 59/02

(52) U.S. Cl. CPC G03F 7/0002; B29C 59/026; B29C 59/022; B29C 59/002; B29K 2701/12

(57) ABSTRACT

A nano-imprinting template, a system, and an imprinting method are provided. The nano-imprinting template (10) comprises: a first baseplate (100) transparent to ultraviolet light; an imprinting pattern structure (105) formed on the first surface of the first baseplate (100); a heating element (110) formed on the second surface, opposite to the first surface, of the first baseplate (100), wherein the heating element (110) is transparent to ultraviolet light; and a first electrode pair (115) formed on the second surface and used for supplying a current applied by an external power supply to the heating element (110) so as to make the heating part (110) generate heat. The nano-imprinting template (10) and the system seamlessly integrate an ultraviolet curing nano-imprinting technology with a thermoplastic nano-imprinting technology, which have the advantages of small size of equipment, low cost, simple process and the like. When the template and the system are used to carry out thermoplastic nano-imprinting, a large area of micro-nano patterns can be copied. In addition, when the template and the system are used to carry out UV curing nano-imprinting, the purposes of improving the process throughput and reducing the pattern replication defects are achieved.

### TECHNICAL FIELD

The present invention relates to the field of nano-imprinting technology, specifically relates to a nano-imprinting template, a system and an imprinting method.

### BACKGROUND ART

Semiconductor surface patterning technique with ultra-high precision is the core and the most advanced technique in micro electronic technology. The current mainstream surface patterning technique used in the large scale manufacturing of integrated circuits is 193 nm immersion lithography technique and secondary patterning technique. With the continuous decrease in the chip size in the future, the existing lithography technology has been unable to meet the need for manufacturing the next generation 22 nm half cycle dynamic random access memory and 16 nm half cycle flash memory.

Nano-imprinting technology is a micro-nano manufacturing technology developed rapidly in recent years on the international plane, and obtains much attention from both academia and industry circles due to characteristics of ultra-high image precision (sub 10 nm), simple process and equipment, high process throughput, and thus is considered to be one of the next generation technologies with low cost and having most potential for manufacturing nano-structures on large scale. Nano-imprinting technology uses mechanical imprinting to copy micro-nano surface structures, and is generally divided into thermoplastic nano-imprinting and UV curing nano-imprinting according to the process and the used materials.

The existing thermoplastic nano-imprinting devices adopt global heating mode, so that the entire template, the substrate and the accessory parts for supporting sample are all heated to imprinting temperature. There are some serious problems with this design as follows. 1) Due to the slow speed of heat conduction, the accessory parts with large mass need longer time for heating and cooling, which results in a longer period (10 to 20 minutes) and a very low process throughput for thermoplastic nano-imprinting. 2) It is very difficult to realize step-and-repeat thermoplastic nano-imprinting and roll-to-roll thermoplastic nano-imprinting. Since the substrate is heated as a whole, the heat transfer between different micro-regions on the substrate occurs, which can lead to re-melting or collapse of the formed patterns in these micro-regions, forming defects, affecting the transfer of the patterns to the substrate. Therefore, the existing thermoplastic nano-imprinting technology is unsuitable to imprint large-area micro-nano patterns. Although a means of enlarging area of the template can be used, this is bound to lead to a decrease in the uniformity of subjected strength and heat, and an increase in the difficulty and cost for template production. 3) Heating accessory parts with large mass requires higher energy consumption and therefore the energy consumption of existing thermoplastic nano-imprinting process is higher.

A step-and-repeat exposure UV curing imprinting technology which is suitable to copy large area of patterns, utilizes a small template, imprints a small area each time, and then moves to the next area to repeat imprinting until the entire surface of the substrate is patterned. This technique improves productivity and reduces the cost, but still faces two problems of high pattern replication defective rate and low process throughput. The bonding force between imprinting template and imprint resist causes the imprint resist tearing or shedding from the substrate during demoulding process. Although the defect rate of nano-imprinting patterns has been decrease greatly by modifying the template and imprint resist, but it still cannot meet the demanding requirements for large-scale industrial production of integrated circuit, especially the defect rate of patterns after the template has copied several thousands of patterns. At present, the international advanced UV curing nano-imprinting device is capable of handling a dozen of silicon wafers per hour. However, such a process throughput has not reached the process throughput of 60-200 silicon wafers per hour required by the production of large-scale integrated circuits. A low process throughput will lead to increased production cost which offsets the advantage of low cost of nano-imprinting technology. Accelerating demolding speed can increase process throughput, but a high demolding speed results in an increase of adhesion force between the template and the imprint resist, making an increase of pattern replication defect rate. Therefore, reducing the adhesive force between the template and the imprint resist is an effective way to solve the problems of both pattern replication defects and process throughput. The adhesive force between the interfaces typically decreases as the temperature increases. Therefore, increasing the temperature for demolding can effectively reduce the adhesive force between the template and the imprint resist. Meanwhile, when curing imprint resist is conducted above room temperature, the curing speed thereof can be improved greatly, the cure is more thorough, and the curing strength is improved. Therefore, both increased process throughput and reduced pattern replication defects can be obtained at the same time by increasing the temperatures for curing and demolding for UV nano-imprinting.

Traditional thermoplastic nano-imprinting and UV curing nano-imprinting require different accessories. At present, all nano-imprinting equipments must be equipped with two separate modules to achieve thermoplastic nano-imprinting and UV curing nano-imprinting respectively. This will cause the equipments have large volume, complex structure and high cost, and cannot complete some special nano-imprinting process.

### CONTENTS OF THE INVENTION

In view of this, the present invention provides a nano-imprinting template, a system and an imprinting method to solve one or more problems involved in the background art.

In a first aspect, the present invention provides a nano-imprinting template, comprising:

a first baseplate transparent to ultraviolet (UV) light;

an imprinting pattern structure, formed on a first surface of the first baseplate;

a heating element, formed on a second surface of the first baseplate opposite to the first surface, wherein the heating element is transparent to ultraviolet light; and

a first electrode pair, formed on the second surface, and used for supplying a current provided by an external power supply to the heating element so as to make the heating element generate heat.

Optionally, the heating element is arranged in such a way that the first baseplate is uniformly heated.

Optionally, the heating element has a strip shape, windingly distributed on the second surface, or a flat layer shape, paved on the second surface; one electrode of the first electrode pair is arranged on one side of the second surface and connected to one end of the heating element, while the other electrode of the first electrode pair is arranged on the other side of the second surface and connected to the other end of the heating element.

Optionally, the material of the heating element is a metal oxide transparent to ultraviolet light.

Optionally, the material of the first electrode pair is a metal oxide transparent to ultraviolet light.

Optionally, the two electrodes of the first electrode pair are respectively connected to the positive and negative poles of the external power supply, and the external power supply can adjust the current supplied to the first electrode pair.

Optionally, the nano-imprinting template further comprises a second baseplate transparent to ultraviolet light, wherein the second baseplate is used to fix the first baseplate, and wherein a second electrode pair is provided on a surface, which faces to the second surface, of the second baseplate, and the second electrode pair is arranged corresponding to the first electrode pair.

Optionally, the two electrodes of the first electrode pair are connected to the positive and negative poles of the external power supply through corresponding electrodes of the second electrode pair respectively.

Optionally, the fixation is a mechanical or electromagnetic fixation.

Optionally, the nano-imprinting template further comprises a magnetic material thin film formed on the surface, which faces to the second surface, of the second baseplate, wherein the magnetic material thin film is used to attract the first baseplate and the second baseplate together by electromagnetic force when an electromagnetic field is formed as the current passes the heating element.

Optionally, the nano-imprinting template further comprises a light diffusing thin film disposed on a surface, which does not face to the second surface, of the second baseplate.

In a second aspect, the present invention provides a nano-imprinting system comprising the nano-imprinting template described in the first aspect and a substrate bearing platform for bearing a substrate to be imprinted.

Optionally, the nano-imprinting system further comprises a thermoelectric cooler mounted on the substrate bearing platform. The thermoelectric cooler comprises a thermoelectric cooling control circuit and a thermoelectric cooling platform, wherein the thermoelectric cooling platform contacts with the substrate to be imprinted, and the thermoelectric cooling control circuit is used to adjust the temperature of the thermoelectric cooling platform.

In a third aspect, the present invention provides a method for carrying out imprinting by using the nano-imprinting system described in the second aspect, comprising the following steps:

S100: heating the heating element so that the temperature of the first baseplate reaches a predetermined temperature, wherein the predetermined temperature is higher than the glass transition temperature of a thermoplastic imprint resist coated on the substrate to be imprinted;

S105: imprinting an imprinting pattern structure into the thermoplastic imprint resist;

S110: stopping heating the heating element and cooling the substrate until the imprinted region is cured;

S115: separating the template from the thermoplastic imprint resist, after which an imprinted pattern is formed in the imprinted region; and

S120: repeating steps S100-S115 until the entire substrate is completely patterned.

Optionally, the step of heating the heating element so that the temperature of the first baseplate reaches a predetermined temperature comprises a step of:

S1000 controlling the current value applied to the first electrode pair by external power supply so as to make the temperature of the first baseplate reach a predetermined temperature.

Optionally, the step of heating the heating element so that the temperature of the first baseplate reaches a predetermined temperature comprises a step of:

S1000 controlling the current value applied to the second electrode pair by external power supply so as to make the temperature of the first baseplate reach a predetermined temperature.

Optionally, the step of cooling the substrate comprises a step of:

S1110: adjusting the temperature of the thermoelectric cooling platform through the thermoelectric cooling control circuit to cool the substrate.

In a fourth aspect, the present invention provides a method for carrying outing imprint by using the nano-imprinting system described in the second aspect, comprising the following steps:

S200: heating the heating element so that the temperature of the first baseplate reaches a predetermined temperature higher than room temperature;

S205: imprinting an imprinting pattern structure into a UV curing imprint resist;

S210: emitting ultraviolet light from the first surface side of the first baseplate so that the imprinted region is cured under the predetermined temperature;

S215: separating the template from the UV curing imprint resist, after which an imprinted pattern is formed in the imprinted region; and

S220: repeating steps S205-S215 until the entire substrate is completely patterned.

Optionally, the step of heating the heating element so that the temperature of the first baseplate reaches a predetermined temperature comprises a step of:

S2000 controlling the current value applied to the first electrode pair by external power supply so as to make the temperature of the first baseplate reach a predetermined temperature.

Optionally, the step of heating the heating element so that the temperature of the first baseplate reaches a predetermined temperature comprises a step of:

S2000 controlling the current value applied to the second electrode pair by external power supply so as to make the temperature of the first baseplate reach a predetermined temperature.

In a fifth aspect, the present invention provides a method for carrying out imprinting by using the nano-imprinting system described in the second aspect, comprising the following steps:

S300: imprinting an imprinting pattern structure into a UV curing imprint resist;

S305: emitting ultraviolet light from the first surface side of the first baseplate;

S310: heating the heating element so that the temperature of the first baseplate reaches a predetermined temperature higher than room temperature, and then curing the imprinted region under the predetermined temperature;

S315: separating the template from the UV curing imprint resist, after which an imprinted pattern is formed in the imprinted region;

S318: stopping heating the heating element so as to cool the first baseplate; and

S320: repeating steps S300-S315 until the entire substrate is completely patterned.

Optionally, the step of heating the heating element so that the temperature of the first baseplate reaches a predetermined temperature comprises a step of:

S3100 controlling the current value applied to the first electrode pair by external power supply so as to make the temperature of the first baseplate reach a predetermined temperature.

Optionally, the step of heating the heating element so that the temperature of the first baseplate reaches a predetermined temperature comprises a step of:

S3100 controlling the current value applied to the second electrode pair by external power supply so as to make the temperature of the first baseplate reach a predetermined temperature.

The present invention combines UV curing nano-imprinting technology and thermoplastic nano-imprinting technology seamlessly by using a transparent template/system with a controllable heat source, and thus can carry out thermoplastic nano-imprinting and UV curing nano-imprinting respectively, and can also realize a synergistic nano-imprint of UV curing and thermoplastic imprint, and has advantages of small size of equipment, low cost, simple process and the like.

When the template/system with controllable heat source of the present invention is applied to thermoplastic nano-imprinting, micro-regions of the imprint resist is heated, and thus copying a large area of micro-nano patterns is achieved by step-and-repeat thermoplastic nano-imprinting technology, and the applicable scope of the thermoplastic nano-imprinting technology is broadened, while the efficiency is improved and the cost is reduced. In addition, it can save energy and reduce the defects caused by the difference of thermal expansion coefficient between the template, the imprint resist and the substrate.

When the template/system with controllable heat source of the present invention is applied to UV curing nano-imprinting, the imprint resist is heated through the template, and the imprint resist is cured at a temperature above room temperature, making the curing rate greatly improved and the exposure time significantly reduced. Therefore, the cure of the imprint resist is more thorough, and the curing strength is improved, thus facilitating the separation of the template and the imprint resist and reducing the defects of the copied patterns. When demolding, since the temperature at the interface between the template and the imprint resist is higher than room temperature, the adhesion force at the interface is reduced significantly compared with that at room temperature, and thus pattern replication defects are reduced. Meanwhile, due to the reduction of interfacial adhesion force, demolding speed can be greatly improved, which also greatly helps to improve the process throughput. Therefore, the purposes of improving the process throughput and reducing the pattern replication defects are achieved.

For some special materials, for example SU-8, the present invention can also achieve synchronous thermoplastic and UV curing imprinting, and can carry out high temperature and UV irradiation simultaneously, and imprint and cure at one step, which greatly simplifying the process for treating such kind of materials and increasing process flexibility. Meanwhile, the present invention also opens up a new direction for the development of novel nano-imprint resist. The novel nano-imprint resist can be reactive to both temperature and ultraviolet light simultaneously to achieve characteristics different from that of the traditional thermoplastic nano-imprint resist and UV curing nano-imprint resist.

Further, the present invention utilizes a thermoelectric cooling system, and thus can control temperature accurately and cool the substrate rapidly, thereby the imprinting circulation speed is increased and the process throughput of the thermoplastic nano-imprinting is greatly improved. The thermoelectric cooling system can generate a temperature lower than ambient temperature, and thus the present invention is also applicable to imprint a material having a curing temperature lower than room temperature, broadening the applicable scope of the traditional thermoplastic nano-imprinting technology.

In addition, using current and voltage to achieve the heating of the template and the cooling of the substrate can control the temperature of the template and substrate accurately by controlling the current and voltage accurately, which provides feasibility of controlling temperature which is important process parameters during nano-imprinting process and provides reproducibility of the nano-imprinting results.

### DESCRIPTION OF FIGURES

Examples will now be explained with reference to the accompanying figures. The figures are intended to explain basic principles and therefore only illustrate necessary components for understanding the basic principles. The figures are not drawn to scale. In the figures, like reference numerals denote like features.

FIGS. 1 (a)-1 (c) show a nano-imprinting template according to an example of the present invention;

FIG. 2 shows a schematic diagram of heating the nano-imprinting template shown in FIG. 1 (a);

FIG. 3 shows a variant of the nano-imprinting template shown in FIG. 1 (a);

FIG. 4 shows a schematic diagram of heating the nano-imprinting template shown in FIG. 3;

FIG. 5 shows a nano-imprinting system according to an example of the present invention;

FIG. 6 shows a flowchart of a method for carrying out thermoplastic nano-imprinting using the nano-imprinting system of the present invention;

FIGS. 7 (a)-7 (e) show schematic system configuration corresponding to each step of the method shown in FIG. 6;

FIG. 8 shows a flowchart of a method for carrying out UV curing nano-imprinting using the nano-imprinting system of the present invention;

FIGS. 9 (a)-9 (d) show schematic system configuration corresponding to each step of the method shown in FIG. 8;

FIG. 10 shows another flowchart of a method for carrying out UV curing nano-imprinting using the nano-imprinting system of the present invention.

### EMBODIMENTS

Hereinafter, the technical solutions of the present invention are further described by the specific embodiments combined with the figure.

### Example 1

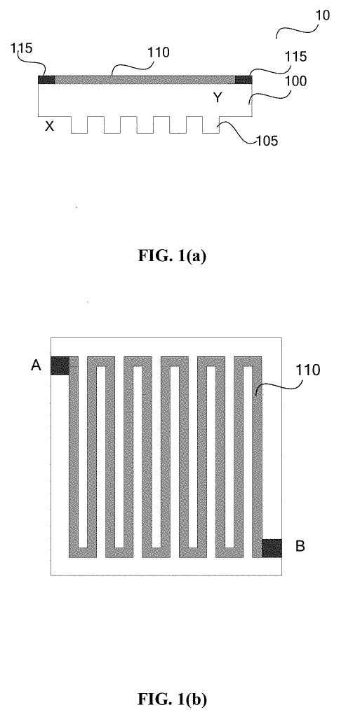

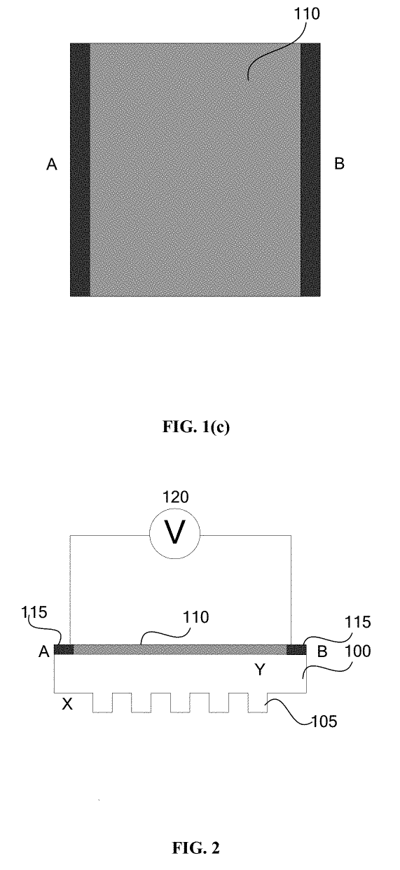

FIGS. 1 (a)-1 (c) show a nano-imprinting template 10 according to Example 1 of the present invention, wherein, FIG. 1 (a) is a front view of the nano-imprinting template 10, and FIGS. 1 (b)-1 (c) are top views of the nano-imprinting template 10, showing two arrangement modes of a heating element.

As shown in FIG. 1 (a), the nano-imprinting template 10 comprises: a first baseplate 100 transparent to ultraviolet light; an imprinting pattern structure 105, formed on a first surface (indicated by X in the figure) of the first baseplate; a heating element 110, formed on a second surface (indicated by Y in the figure) of the first baseplate opposite to the first surface, wherein the heating element 110 is transparent to ultraviolet light; and a first electrode pair 115, formed on the second surface, and used for supplying a current provided by an external power supply to the heating element 110 to make the heating element 110 generate heat.

Wherein, the first baseplate 100 may be made of UV-transparent double-side polished quartz glass flat plate. The imprinting pattern structure 105 may be formed by producing surface micro-nano protrusions using micronano fabrication techniques (such as electron beam patterning or dry etching techniques). The materials of the heating element 110 and the first electrode pair 115 can be metal oxides transparent to ultraviolet light (such as ITO, IZnO, ZnO or InO, etc.), and the two can be formed by thin film deposition, photoetching, dry etching and wet etching. The second surface of the first baseplate 100 is required to remain flat, in order to ensure uniform pressure during imprinting.

As shown in FIG. 2, when imprinting, through loading a voltage on the first electrode pair 115 by an external power supply 120, i.e., the two electrodes A/B of the first electrode pair being connected to the positive and negative poles of the external power supply 120 respectively, the external power supply can adjust the current supplied to the first electrode pair. The heating element heats the first baseplate 100 through the current, and the temperature can be up to 100° C. or higher. The shape, size of cross-sectional area, and the electrical conductivity of the material of the heating element 100 on the second surface of the first baseplate 100 will affect the generation of the heat after the current is switched on and the final temperature of the template. Different resistance values can be obtained by selecting different deposition methods. A uniform heating of the entire first baseplate is achieved by optimizing the shape and density of the heating element. FIG. 1 (b) shows one arrangement form of the heating element 110. As shown in FIG. 1 (b), the heating element 110 has a strip shape and is windingly distributed on the second surface. One electrode A of the first electrode pair is arranged on one side of the second surface and connected to one end of the heating element 110, while the other electrode B of the first electrode pair is arranged on the other side of the second surface and connected to the other end of the heating element 110. FIG. 1 (c) shows one arrangement form of the heating element 110. As shown in FIG. 1 (c), the heating element 110 has a flat layer shape and is paved on the second surface. One electrode A of the first electrode pair is arranged on one side of the second surface and connected to one end of the heating element 110, while the other electrode B of the first electrode pair is arranged on the other side of the second surface and connected to the other end of the heating element 110. After the template is fabricated, the temperature of the first baseplate 100 during the nano-imprinting process can be controlled by the loaded current value. Since the current can be precisely controlled by the external power supply, the temperature of the first baseplate 100 can be precisely controlled to an accuracy within 0.1° C., which cannot be achieved using the existing thermoplastic nano-imprinting equipment. Due to the presence of the accessory parts, the existing thermoplastic nano-imprinting equipment cannot accurately monitor the actual temperature of the template, and therefore cannot accurately control the imprinting temperature during the imprinting process.

### Example 2

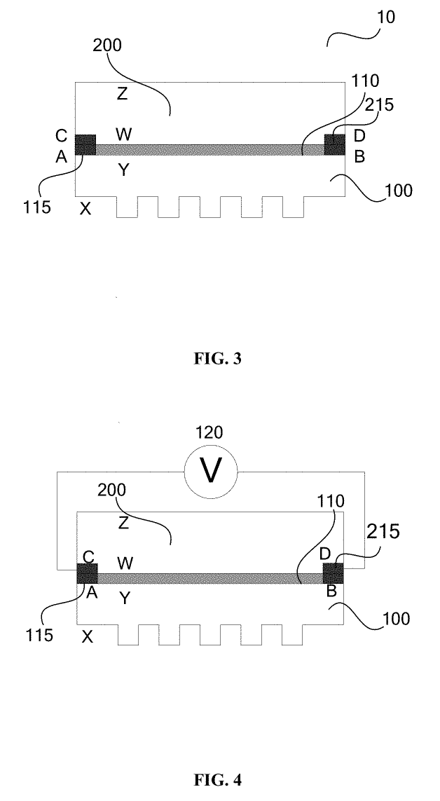

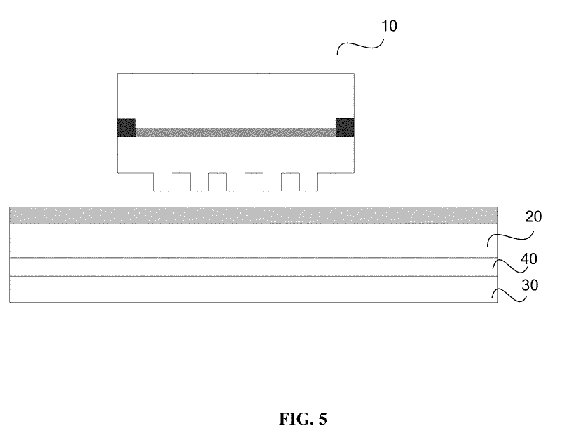

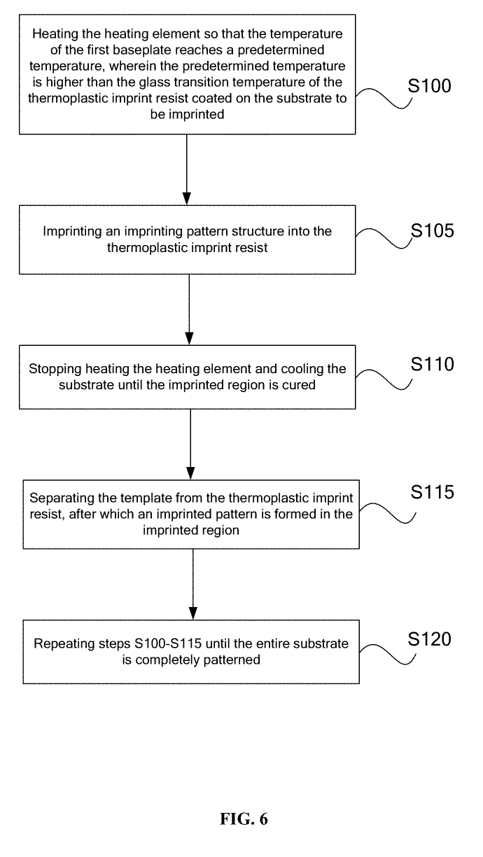

As a variant of the above-mentioned nano-imprinting template 10, shown in FIG. 3, the nano-imprinting template 10 further includes a second baseplate 200 transparent to ultraviolet light, wherein the second baseplate 200 has two functions. On one hand, the second baseplate 200 fixes the first baseplate 100 and applies mechanical pressure around the support frame of the second baseplate 200, which can provide a working pressure required for nano-imprinting. The fixation can be carried out by two ways of mechanical or electromagnetic fixation. Wherein, with respect to electromagnetic fixation, the nano-imprinting template further includes a magnetic material thin film formed on the surface (indicated by W in the figure) of the second baseplate 200, said surface opposites to the second surface of the first baseplate, for attracting the first baseplate and the second baseplate together by electromagnetic force when an electromagnetic field is formed as the current passes heating element 110. On the other hand, the second baseplate 200 is used to provide a current for the first baseplate 100 by connecting the above integrated electrode pair to the first electrode pair on the first baseplate through direct contact. Specifically, a second electrode pair 215 is arranged on a surface of the second baseplate 200, said surface facing to the second surface of the first baseplate 100, said second electrode pair 215 being arranged corresponding to the first electrode pair 115.

In the presence of a second baseplate 200, as shown in FIG. 4, when imprinting, through loading a voltage on the second electrode pair 215 by an external power supply 120, i.e., the two electrodes C/D of the second electrode pair being connected to positive and negative poles of external power supply 120 respectively, and then through the first electrode pair A/B which are directly contacted, the two electrodes C/D of the second electrode pair provide a current to the heating element 110. The external power supply 120 can adjust the current supplied to the first electrode pair. The heating element heats the first baseplate 100 through the current, and the temperature can be up to 100° C. or higher.

The ultraviolet light source can be introduced from the top of the support frame. In order to ensure uniformity of the incident ultraviolet light, a light diffusing thin film is disposed on the ultraviolet light incident side of the support frame, that is, the nano-imprinting template further comprises a light diffusing thin film disposed on a surface (indicated by Z in the figure), which does not face to the second surface of the first baseplate 100, of the second baseplate 200.

### Example 3

The present invention also provides a nano-imprinting system comprising a nano-imprinting template 10 described in Example 1 or Example 2 and a substrate bearing platform 30 for bearing a substrate to be imprinted, as shown in FIG. 4. Please note that FIG. 4 shows a case comprising the nano-imprinting template 10 described in Example 2 (namely comprising the second baseplate 200).

Different from traditional nano-imprinting utilizing water cooling or air cooling ways, in the present invention, a thermoelectric cooler can be mounted on the substrate bearing platform 20, in order to cool the substrate rapidly and control cooling temperature precisely. Further, the use of the thermoelectric cooler may produce a temperature lower than the ambient temperature, and therefore the nano-imprinting system can be used for imprinting an imprint resist having a curing temperature lower than room temperature. Specifically, the thermoelectric cooler comprises a thermoelectric cooling control circuit (not shown in the figure) and a thermoelectric cooling platform 40, wherein the thermoelectric cooling platform 40 contacts with the substrate 20 to be imprinted, and the thermoelectric cooling control circuit is used to adjust the temperature of the thermoelectric cooling platform 40.

### Example 4

This example provides a method for applying the nano-imprinting template/system of the present invention to thermoplastic nano-imprinting.

As shown in FIG. 6, the method comprises the following steps.

S100: heating the heating element so that the temperature of the first baseplate reaches a predetermined temperature, wherein the predetermined temperature is higher than the glass transition temperature of the thermoplastic imprint resist coated on the substrate to be imprinted.

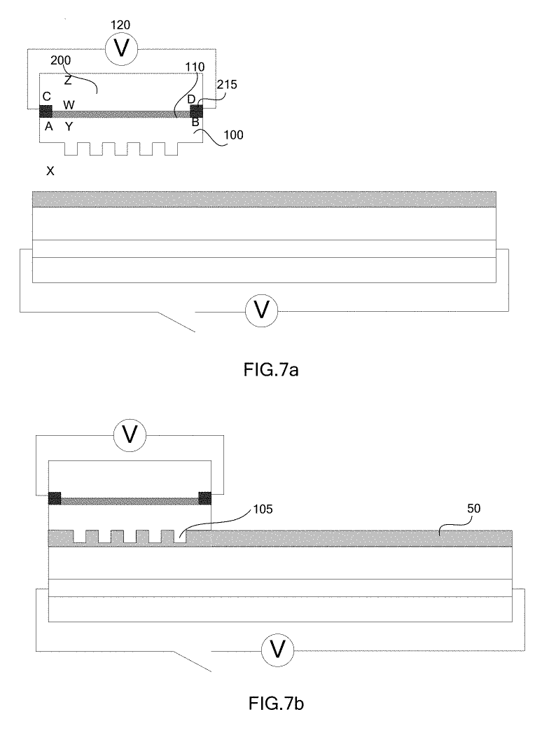

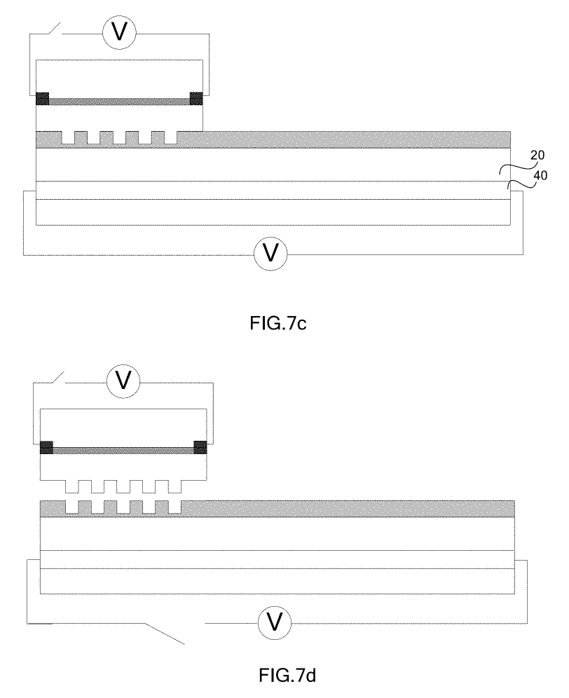

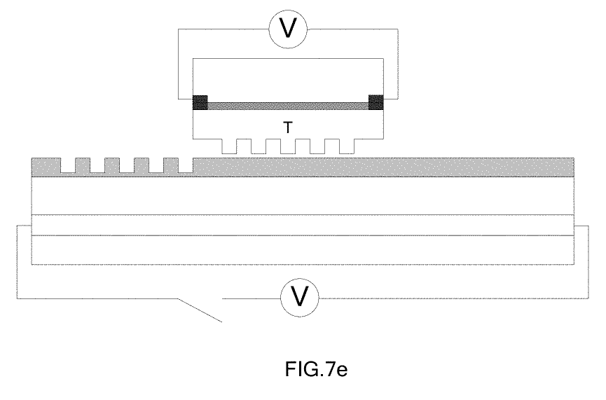

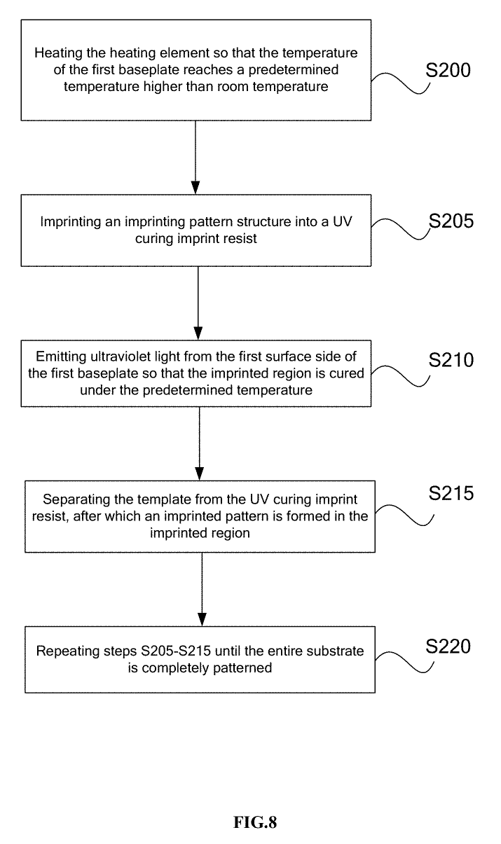

In the presence of a second substrate 200, as shown in FIG. 7 (a), the step of heating the heating element 110 so that the temperature of the first baseplate reaches a predetermined temperature comprises a step of

S1000 controlling the current value applied to the second electrode pair 215 by external power supply 120 so as to make the temperature of the first baseplate reach a predetermined temperature.

In this step, the temperature of the entire template comprising both the first baseplate 100 and the second baseplate 200 can reach said predetermined temperature. However, in order to achieve the purposes of the present invention, only making the temperature of the first baseplate reach said predetermined temperature is enough, which can save energy at the same time.

Similarly, although not shown in the figures, those skilled in the art will appreciate that, when there is only the first baseplate 100 without the second baseplate 200, the step of heating the heating element 110 so that the temperature of the first baseplate reaches a predetermined temperature comprises a step of

S1000 controlling the current value applied to the first electrode pair by external power supply so as to make the temperature of the first baseplate reach a predetermined temperature.

In the following, the explanation will be continued taking the structure of FIG. 7 (a) as an example.

S105: imprinting an imprinting pattern structure into the thermoplastic imprint resist.

As shown in FIG. 7 (b), a certain mechanical pressure is applied around the upper surface of the second baseplate, so that the imprinting pattern structure 105 contacts with thermoplastic imprint resist 50. The portion contacting with the template is heated and melted, and fills the micro-nano cavities among the convex parts of the imprinting pattern structure 105 under the action of the pressure, until all the micro-nano cavities on the template are sufficiently filled.

S110: stopping heating the heating element and cooling the substrate until the imprinted region is cured.

Preferably, in the presence of a thermoelectric cooler of the present invention, cooling the substrate 20 comprises a step of disconnecting the voltage on the second electrode, and adjusting the temperature of the thermoelectric cooling platform 40 by the thermoelectric cooling control circuit to cool the substrate 20, until the imprinted region is completely cured, and then turning off the thermoelectric cooler, as shown in FIG. 7 (c).

S115: separating the template from the thermoplastic imprint resist, after which an imprinting pattern is formed in the imprinted region, as shown in FIG. 7 (d).

S120: repeating steps S100-S115 until the entire substrate is completely patterned, as shown in FIG. 7 (e).

A step-and-repeat imprinting mode simplifies the imprinting process, reduces cost and improves efficiency, and is suitable to copy large area of patterns. Traditional thermoplastic nano-imprinting technologies heat the entire template and substrate, and cannot accurately carry out localized heat to the imprint resist due to its own technical limitations. Therefore, when imprinting by step-and-repeat imprinting mode, since the substrate is heated integrally, when the template moves from one micro-region to the next, the pattern having been formed in the previous micro-region remelts or collapses, forming defects. Therefore, a step-and-repeat thermoplastic nano-imprinting cannot be achieved.

The method of this example overcomes the above problems. By using a template with a controllable heat source and carrying out micro-region heating to the imprint resist, this method achieves the purpose of copying large area of patterns using a step-and-repeat thermoplastic nano-imprinting technology and broadens the applicable scope of the thermoplastic nano-imprinting technology, while improving the efficiency and reducing the cost. In addition, compared to the traditional thermoplastic nano-imprinting technology, the present invention saves energy and reduces the defects caused by the difference of thermal expansion coefficient between the template, the imprint resist and the substrate by carrying out micro-region heating to the imprint resist through a template.

Further, the present invention utilizes a thermoelectric cooler, and thus can control temperature accurately and cool the substrate rapidly, thereby the temperature circulation speed is accelerated and the imprinting circulation speed is increased, and the process throughput of the thermoplastic nano-imprinting is greatly improved. The thermoelectric cooler can generate a temperature lower than ambient temperature, and thus the present method is also applicable to imprint a material having a curing temperature lower than room temperature, obtaining micro-nano patterns on those materials, which broadens the applicable scope of the traditional thermoplastic nano-imprinting technology.

### Example 5

This example provides a method for applying the nano-imprinting template/system of the present invention to UV curing nano-imprinting. As shown in FIG. 8, the method comprises the following steps.

S200: heating the heating element so that the temperature of the first baseplate reaches a predetermined temperature higher than room temperature, for example 60° C. to 80° C.

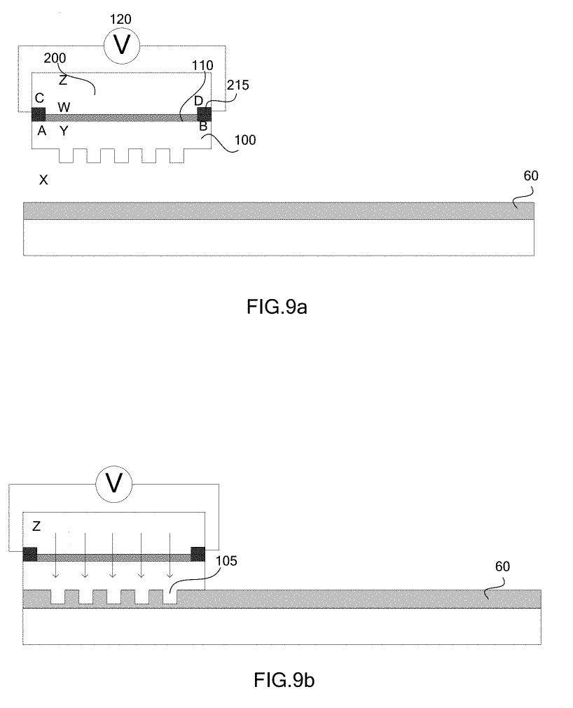

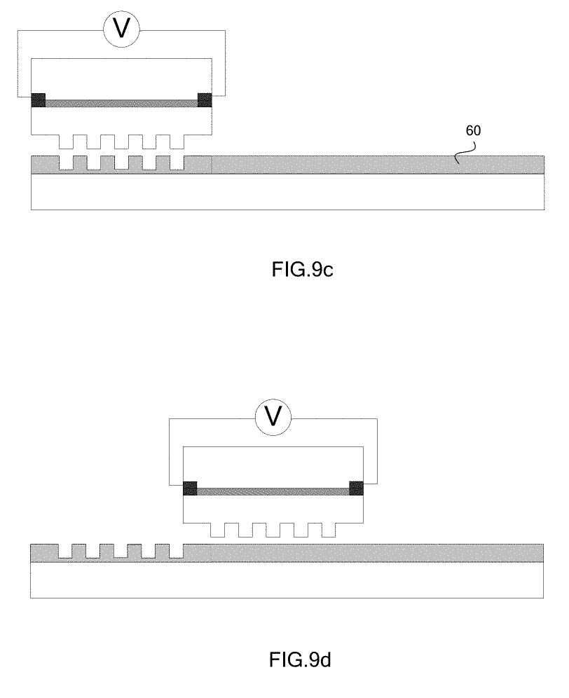

In the presence of a second baseplate 200, as shown in FIG. 9 (a), the step of heating the heating element 110 so that the temperature of the first baseplate reaches a predetermined temperature higher than room temperature comprises the step of

S2000 controlling the current value applied to the second electrode pair 215 by external power supply 120 so as to make the temperature of the first baseplate reach a predetermined temperature higher than room temperature.

In this step, the temperature of the entire template comprising both the first baseplate 100 and the second baseplate 200 can reach said predetermined temperature. However, in order to achieve the purposes of the present invention, only making the temperature of the first baseplate reach said predetermined temperature is enough, which can save energy at the same time.

Similarly, although not shown in the figures, those skilled in the art will appreciate that, when there is only the first baseplate 100 without the second baseplate 200, the step of heating the heating element 110 so that the temperature of the first baseplate reaches a predetermined temperature higher than room temperature comprises the step of

S2000 controlling the current value applied to the first electrode pair by external power supply so as to make the temperature of the first baseplate reach a predetermined temperature higher than room temperature.

In the following, the explanation will be continued taking the structure of FIG. 9 (a) as an example.

S205: imprinting an imprinting pattern structure into a UV curing imprint resist.

As shown in FIG. 9 (b), a certain mechanical pressure is applied around the upper surface (indicated by Z in the figure) of the second baseplate, so that the imprinting pattern structure 105 contacts with thermoplastic imprint resist 50, filling the micro-nano cavities among the convex parts of the imprinting pattern structure 105 under the action of the pressure, until all the micro-nano cavities on the template are sufficiently filled.

S210: emitting ultraviolet light from the first surface side of the first baseplate so that the imprinted region is cured under the predetermined temperature.

As shown by the arrows in FIG. 9 (b), ultraviolet light is emitted from the surface side indicated by Z. As described above, both the first baseplate 100 and the second baseplate 200 are transparent to ultraviolet light, and the heating element is also transparent to ultraviolet light. Therefore, ultraviolet light can come into the UV curing imprint resist, and cure the UV curing imprint resist. At this moment, the regions of the UV curing imprint resist contacting with the template is heated by the template and cured at a temperature higher than room temperature.

S215: separating the template from the UV curing imprint resist, after which an imprinting pattern is formed in the imprinted region.

As shown in FIG. 9 (c), after the imprint resist is completely cured, the template and the imprint resist 60 are treated to separate from each other at a certain speed. At this moment, as the temperature at the interface between the template and the imprint resist is higher than room temperature, the adhesion force at the interface is reduced significantly compared with that at room temperature, and thus the template and the imprint resist 60 are separated smoothly, forming unbroken micro-nano structures in the imprint resist 60.

S220: repeating steps S205-S215 until the entire substrate is completely patterned, as shown in FIG. 9 (d).

### Example 6

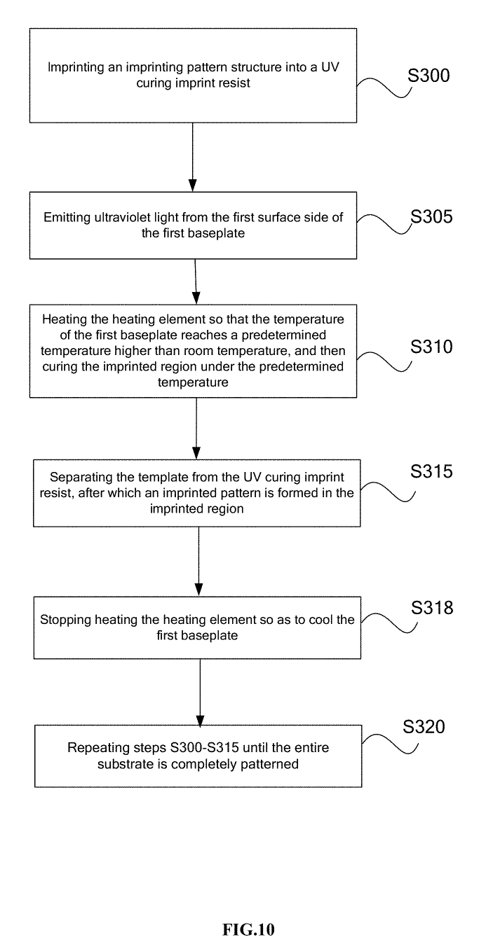

This example is a variant of Example 5. As shown in FIG. 10, the method comprises the following steps.

S300: imprinting an imprinting pattern structure into a UV curing imprint resist.

A certain mechanical pressure is applied around the upper surface of the second baseplate, so that the imprinting pattern structure contacts with thermoplastic imprint resist, filling the micro-nano cavities among the convex parts of the imprinting pattern structure under the action of the pressure, until all the micro-nano cavities on the template are sufficiently filled.

S305: emitting ultraviolet light from the first surface side of the first baseplate.

As described above, both the first baseplate and the second baseplate are transparent to ultraviolet light, and the heating element is also transparent to ultraviolet light. Therefore, ultraviolet light can come into the UV curing imprint resist.

S310: heating the heating element so that the temperature of the first baseplate reaches a predetermined temperature (for example 60° C. to 80° C.) higher than room temperature, and then curing the imprinted region under the predetermined temperature.

In the presence of a second baseplate, the step of heating the heating element so that the temperature of the first baseplate reaches a predetermined temperature higher than room temperature comprises the step of

S3100 controlling the current value applied to the second electrode pair by external power supply so as to make the temperature of the first baseplate reach a predetermined temperature higher than room temperature.

In this step, the temperature of the entire template comprising both the first baseplate 100 and the second baseplate 200 can reach said predetermined temperature. However, in order to achieve the purposes of the present invention, only making the temperature of the first baseplate reach said predetermined temperature is enough, which can save energy at the same time.

Similarly, although not shown in the figures, those skilled in the art will appreciate that, when there is only the first baseplate without the second baseplate, the step of heating the heating element so that the temperature of the first baseplate reaches a predetermined temperature higher than room temperature comprises the step of

S3100 controlling the current value directly applied to the first electrode pair by external power supply so as to make the temperature of the first baseplate reach a predetermined temperature higher than room temperature.

S315: separating the template from the UV curing imprint resist, after which an imprinting pattern is formed in the imprinted region.

After the imprint resist is completely cured, the template and the imprint resist 60 are treated to separate from each other at a certain speed. At this moment, as the temperature at the interface between the template and the imprint resist is higher than room temperature, the adhesion force at the interface is reduced significantly compared with that at room temperature, and thus the template and the imprint resist are separated smoothly, forming unbroken micro-nano structures in the imprint resist.

S318: stopping heating the heating element so as to cool the substrate.

S320: repeating steps S300-S315 until the entire substrate is completely patterned.

This example firstly imprints micro-nano pattern on the template into imprint resist and exposes it to ultraviolet light, and then applies voltage to the template and heats the template and imprint resist. With doing this, it can avoid that some imprint resists change their curing characteristics for being affected by the temperature. Heating and exposing independently brings great flexibility to nano-imprinting process.

In traditional UV curing imprinting technology, a certain UV exposure time is required for each imprinting process. Taking into account that hundreds times of imprinting, exposure and demolding is required for the completion of 8 inch or 12 inch wafer, if the exposure time is reduced and the demolding speed is increased, the process throughput will be improved greatly. Generally, curing speed shows an exponential relationship with temperature, so the curing speed will be increased several dozen times if the temperature is raised to 60° C. to 80° C. In Examples 5 and 6, the imprint resist is cured at a temperature higher than room temperature by heating the template, and thus the curing speed is greatly improved, and the exposure time is significantly reduced. Compared with traditional UV curing nano-imprinting technology, the process speed is increased. Meanwhile, at a temperature higher than room temperature, the cure of imprint resist is more thorough, and the curing strength is improved, thereby the separation of template and imprint resist is facilitated and the pattern replication defects are reduced. Generally, the interface adhesion decreases as the temperature rises, thus demolding at a temperature higher than room temperature can effectively reduce the interface adhesion and the pattern replication defects. In addition, due to the decrease of interface adhesion, the demolding can be greatly improved, which also greatly helps to enhance the process throughput. Therefore, by utilizing a template with a controllable heat source, this example can successfully achieve a dual purpose of improving process throughput of UV imprinting and reducing pattern replication defects.

In addition, for some special materials, for example SU-8, the present invention can also achieve synchronous thermoplastic and UV curing imprinting, and can carry out high temperature and UV irradiation simultaneously, and imprint and cure at one step, which greatly simplifying the process for treating such kind of materials.

The foregoing is only preferred embodiments of the present invention and is not intended to limit the present invention. For those skilled in the art, the present invention can have various modifications and variations. Any modification, equivalent replacement, improvement and the like within the spirit and principle of the present invention should be included in the scope of the present invention.

1. A nano-imprinting template, comprising:
a first baseplate transparent to ultraviolet light;
an imprinting pattern structure, formed on a first surface of the first baseplate;
a heating element, formed on a second surface of the first baseplate opposite to the first surface, wherein the heating element is transparent to ultraviolet light; and
a first electrode pair, formed on the second surface, and used for supplying a current provided by an external power supply to the heating element so as to make the heating element generate heat.

2. The nano-imprinting template according to claim 1, characterized in that the heating element is arranged in such a way that the first baseplate is uniformly heated.

3. The nano-imprinting template according to claim 2, characterized in that
the heating element has a strip shape, windingly distributed on the second surface, or a flat layer shape, paved on the second surface;
one electrode of the first electrode pair is arranged on one side of the second surface and connected to one end of the heating element, while the other electrode of the first electrode pair is arranged on the other side of the second surface and connected to the other end of the heating element.

4. The nano-imprinting template according to claim 3, characterized in that the material of the heating element is a metal oxide transparent to ultraviolet light.

5. The nano-imprinting template according to claim 1, characterized in that the material of the first electrode pair is a metal oxide transparent to ultraviolet light.

6. The nano-imprinting template according to claim 1, characterized in that the two electrodes of the first electrode pair are respectively connected to the positive and negative poles of the external power supply, and the external power supply can adjust the current supplied to the first electrode pair.

7. The nano-imprinting template according to claim 1, characterized in that the nano-imprinting template further comprises a second baseplate transparent to ultraviolet light, wherein the second baseplate is used to fix the first baseplate, and wherein a second electrode pair is provided on a surface of the second baseplate, said surface facing to the second surface, and the second electrode pair is arranged corresponding to the first electrode pair.

8. The nano-imprinting template according to claim 7, characterized in that the two electrodes of the first electrode pair are connected to the positive and negative poles of the external power supply through corresponding electrodes of the second electrode pair respectively.

9. The nano-imprinting template according to claim 7, characterized in that the fixation is a mechanical or electromagnetic fixation.

10. The nano-imprinting template according to claim 9, characterized in that the nano-imprinting template further comprises a magnetic material thin film formed on the surface, which faces to the second surface, of the second baseplate, wherein the magnetic material thin film is used to attact the first baseplate and the second baseplate together by electromagnetic force when an electromagnetic field is formed as the current passes the heating element.

11. The nano-imprinting template according to claim 7, characterized in that the nano-imprinting template further comprises a light diffusing thin film disposed on a surface, which does not face to the second surface, of the second baseplate.

12. A nano-imprinting system comprising the nano-imprinting template according to claim 1 and a substrate bearing platform for bearing a substrate to be imprinted.

13. The nano-imprinting system according to claim 12, characterized in that the nano-imprinting system further comprises a thermoelectric cooler mounted on the substrate bearing platform, wherein the thermoelectric cooler comprises a thermoelectric cooling control circuit and a thermoelectric cooling platform, wherein the thermoelectric cooling platform contacts with the substrate to be imprinted, and the thermoelectric cooling control circuit is used to adjust the temperature of the thermoelectric cooling platform.

14. A method for carrying out imprinting by using the nano-imprinting system according to claim 12, comprising the following steps:
S100: heating the heating element so that the temperature of the first baseplate reaches a predetermined temperature, wherein the predetermined temperature is higher than the glass transition temperature of a thermoplastic imprint resist coated on the substrate to be imprinted;
S105: imprinting an imprinting pattern structure into the thermoplastic imprint resist;
S110: stopping heating the heating element and cooling the substrate until the imprinted region is cured;
S115: separating the template from the thermoplastic imprint resist, after which an imprinted pattern is formed in the imprinted region; and
S120: repeating steps S100-S115 until the entire substrate is completely patterned.

15. The method according to claim 14, characterized in that when using the nano-imprinting template of claim 6, the step of heating the heating element so that the temperature of the first baseplate reaches a predetermined temperature comprises a step of S1000 controlling the current value applied to the first electrode pair by external power supply so as to make the temperature of the first baseplate reach a predetermined temperature.

16. The method according to claim 14, characterized in that when using the nano-imprinting template of claim 8, the step of heating the heating element so that the temperature of the first baseplate reaches a predetermined temperature comprises a step of
S1000 controlling the current value applied to the second electrode pair by external power supply so as to make the temperature of the first baseplate reach a predetermined temperature.

17. The method according to claim 14, characterized in that when using the nano-imprinting system of claim 13, the step of cooling the substrate comprises a step of
S1110: adjusting the temperature of the thermoelectric cooling platform through the thermoelectric cooling control circuit to cool the substrate.

18. A method for carrying out imprint by using the nano-imprinting system according to claim 12, comprising the following steps:
S200: heating the heating element so that the temperature of the first baseplate reaches a predetermined temperature higher than room temperature;
S205: imprinting an imprinting pattern structure into a UV curing imprint resist;
S210: emitting ultraviolet light from the first surface side of the first baseplate so that the imprinted region is cured under the predetermined temperature;
S215: separating the template from the UV curing imprint resist, after which an imprinted pattern is formed in the imprinted region; and
S220: repeating steps S205-S215 until the entire substrate is completely patterned.

19. The method according to claim 18, characterized in that when using the nano-imprinting template of claim 6, the step of heating the heating element so that the temperature of the first baseplate reaches a predetermined temperature higher than room temperature comprises a step of
S2000 controlling the current value applied to the first electrode pair by external power supply so as to make the temperature of the first baseplate reach a predetermined temperature higher than room temperature.

20. The method according to claim 18, characterized in that when using the nano-imprinting template of claim 8, the step of heating the heating element so that the temperature of the first baseplate reaches a predetermined temperature higher than room temperature comprises the step of
S2000 controlling the current value applied to the second electrode pair by external power supply so as to make the temperature of the first baseplate reach a predetermined temperature higher than room temperature.

21. A method for carrying out imprint by using the nano-imprinting system according to claim 12, comprising the following steps:
S300: imprinting an imprinting pattern structure into a UV curing imprint resist;
S305: emitting ultraviolet light from the first surface side of the first baseplate;
S310: heating the heating element so that the temperature of the first baseplate reaches a predetermined temperature higher than room temperature, and then curing the imprinted region under the predetermined temperature;
S315: separating the template from the UV curing imprint resist, after which an imprinted pattern is formed in the imprinted region;
S318: stopping heating the heating element so as to cool the first baseplate; and
S320: repeating steps S300-S315 until the entire substrate is completely patterned.

22. The method according to claim 21, characterized in that when using the nano-imprinting template of claim 6, the step of heating the heating element so that the temperature of the first baseplate reaches a predetermined temperature comprises a step of
S3100 controlling the current value applied to the first electrode pair by external power supply so as to make the temperature of the first baseplate reach a predetermined temperature.

23. The method according to claim 21, characterized in that when using the nano-imprinting template of claim 8, the step of heating the heating element so that the temperature of the first baseplate reaches a predetermined temperature comprises a step of
S3100 controlling the current value applied to the second electrode pair by external power supply so as to make the temperature of the first baseplate reach a predetermined temperature.
